(19) United States
(12) Patent Application Publication
(10) Pub. No.: US 2024/0030080 A1
(43) Pub. Date: Jan. 25, 2024

(54) SEMICONDUCTOR DEVICE

(71) Applicant: ROHM CO., LTD., Kyoto-shi, Kyoto (JP)

(72) Inventor: Akihiro KOGA, Kyoto-shi, Kyoto (JP)

(21) Appl. No.: 18/255,952

(22) PCT Filed: Jan. 5, 2022
(86) PCT No.: PCT/JP2022/000123

§ 371 Date: Jun. 5, 2023

(30) Foreign Application Priority Data
Jan. 18, 2021 (JP) 2021-005628

(51) Int. Cl. H01L 23/31; H01L 23/498

(52) U.S. Cl. CPC H01L 23/315; H01L 23/49844; H01L 23/49805; H01L 24/73

(57) ABSTRACT

A semiconductor device includes: a semiconductor element; a plurality of first leads electrically connected to the semiconductor element; and a sealing resin having a top surface and a bottom surface facing away from each other in a thickness direction of the semiconductor element, the sealing resin covering the semiconductor element and a portion of each of the first leads. The sealing resin has an opening extending from the top surface to the bottom surface. Each of the plurality of first leads has a covered portion covered with the sealing resin, and an exposed portion connected to the covered portion and exposed from the sealing resin. As viewed in the thickness direction, at least one of the exposed portions of the plurality of first leads is housed in the opening.

### TECHNICAL FIELD

The present disclosure relates to a semiconductor device.

### BACKGROUND ART

Patent document 1 discloses an example of a semiconductor device provided with a MOSFET as a semiconductor element (semiconductor pellet). The semiconductor device includes a drain lead to which source voltage is applied; an island section that is connected to the drain lead and on which the MOSFET is mounted; a gate lead for inputting an electric signal to the MOSFET; and a source lead through which a current converted by the MOSFET based on the source voltage and the electric signal flows. The MOSFET has two metal electrodes that are electrically connected to the source and gate of the MOSFET. Metal clips are bonded to the two metal electrodes and also to the source lead and the gate lead, respectively. This reduces parasitic resistance and inductance as compared to the case where wires are bonded to the two electrodes and the source and gate leads, thus improving the power conversion efficiency in the semiconductor device.

In recent years, semiconductor devices, provided with a MOSFET including a compound semiconductor substrate made of silicon carbide (SiC), for example, have become increasingly in use. The MOSFET has advantages over previous MOSFETs in that it has a smaller size and provides improved power conversion efficiency. When the MOSFET is employed for the semiconductor device disclosed in Patent document 1, the size of the semiconductor device can be reduced. However, in the semiconductor device, portions of the drain lead, the source lead, and the gate lead protrude from the resin. As such, the size reduction of the semiconductor device results in the distances between the leads being smaller, which poses a problem of lowering the dielectric strength of the semiconductor device.

### PRIOR ART DOCUMENT

### Patent Document

Patent Document 1: JP-A-2001-274206

### SUMMARY OF THE INVENTION

### Problem to be Solved by the Invention

In view of the above circumstances, an object of the present disclosure is to provide a semiconductor device that can be more compact while suppressing a decrease in the dielectric strength.

### Means to Solve the Problem

Provided by a first aspect of the present disclosure, a semiconductor device includes: a semiconductor element; a plurality of first leads electrically connected to the semiconductor element; and a sealing resin having a top surface and a bottom surface facing away from each other in a thickness direction of the semiconductor element, the sealing resin covering the semiconductor element and a portion of each of the first leads. The sealing resin has an opening extending from the top surface to the bottom surface. Each of the plurality of first leads has a covered portion covered with the sealing resin, and an exposed portion connected to the covered portion and exposed from the sealing resin. As viewed in the thickness direction, at least one of the exposed portions of the plurality of first leads is housed in the opening.

### Advantages of the Invention

The configuration described above can reduce the size of the semiconductor device while suppressing a decrease in the dielectric strength of the semiconductor device.

Other features and advantages of the present disclosure will be more apparent from the detailed description given below with reference to the accompanying drawings.

### BRIEF DESCRIPTION OF THE DRAWINGS

FIG. 1 is a plan view illustrating a semiconductor device according to a first embodiment of the present disclosure.

FIG. 2 is a bottom view illustrating the semiconductor device in FIG. 1.

FIG. 3 is a bottom view corresponding to FIG. 2, as seen through a sealing resin.

FIG. 4 is a front view illustrating the semiconductor device in FIG. 1.

FIG. 5 is a rear view illustrating the semiconductor device in FIG. 1.

FIG. 6 is a cross-sectional view taken along line VI-VI in FIG. 3.

FIG. 7 is a cross-sectional view taken along line VII-VII in FIG. 3.

FIG. 8 is a partially enlarged view of FIG. 6.

FIG. 9 is a partially enlarged view of FIG. 6.

FIG. 10 is a partially enlarged cross-sectional view of a first variation of the semiconductor device in FIG. 1.

FIG. 11 is a partially enlarged cross-sectional view of a second variation of the semiconductor device in FIG. 1.

FIG. 12 is a plan view illustrating a semiconductor device according to a second embodiment of the present disclosure.

FIG. 13 is a bottom view illustrating the semiconductor device in FIG. 12.

FIG. 14 is a front view illustrating the semiconductor device in FIG. 12.

FIG. 15 is a rear view illustrating the semiconductor device in FIG. 12.

FIG. 16 is a cross-sectional view taken along line XVI-XVI in FIG. 13.

FIG. 17 is a plan view illustrating a semiconductor device according to a third embodiment of the present disclosure.

FIG. 18 is a bottom view of the semiconductor device in FIG. 17, as seen through a sealing resin.

FIG. 19 is a cross-sectional view taken along line XIX-XIX in FIG. 18.

FIG. 20 is a cross-sectional view taken along line XX-XX in FIG. 18.

FIG. 21 is a bottom view illustrating a semiconductor device according to a fourth embodiment of the present disclosure.

FIG. 22 is a bottom view corresponding to FIG. 21, as seen through a sealing resin.

FIG. 23 is a cross-sectional view taken along line XXIII-XXIII in FIG. 22.

FIG. 24 is a bottom view illustrating a variation of the semiconductor device in FIG. 21.

FIG. 25 is a cross-sectional view taken along line XXV-XXV in FIG. 24.

FIG. 26 is a bottom view illustrating a semiconductor device according to a fifth embodiment of the present disclosure.

FIG. 27 is a cross-sectional view taken along line XXVII-XXVII in FIG. 26.

FIG. 28 is a bottom view illustrating a variation of the semiconductor device in FIG. 26.

FIG. 29 is a bottom view illustrating a semiconductor device according to a sixth embodiment of the present disclosure.

FIG. 30 is a cross-sectional view taken along line XXX-XXX in FIG. 29.

FIG. 31 is a cross-sectional view taken along line XXXI-XXXI in FIG. 29.

### MODE FOR CARRYING OUT THE INVENTION

Embodiments of the present disclosure will be described with reference to the accompanying drawings.

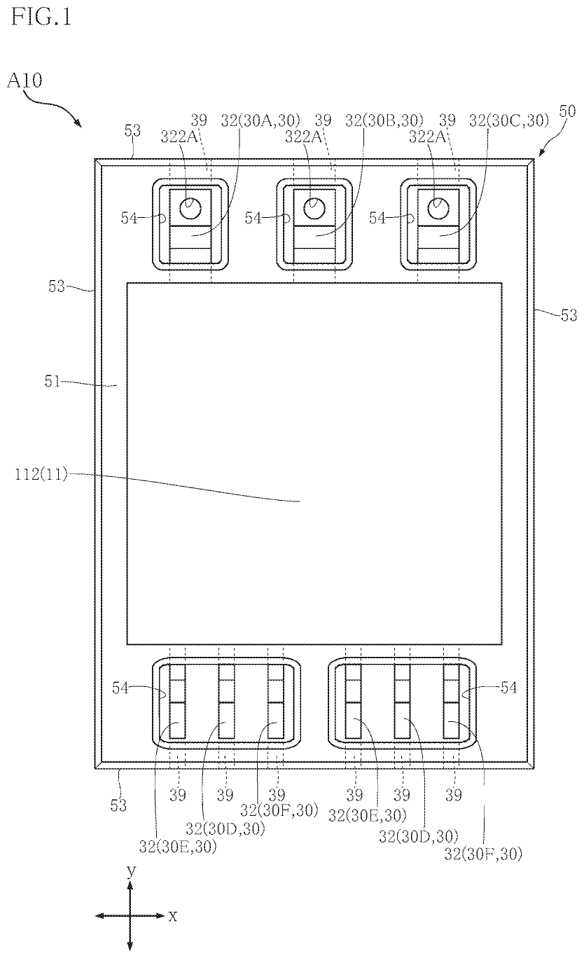

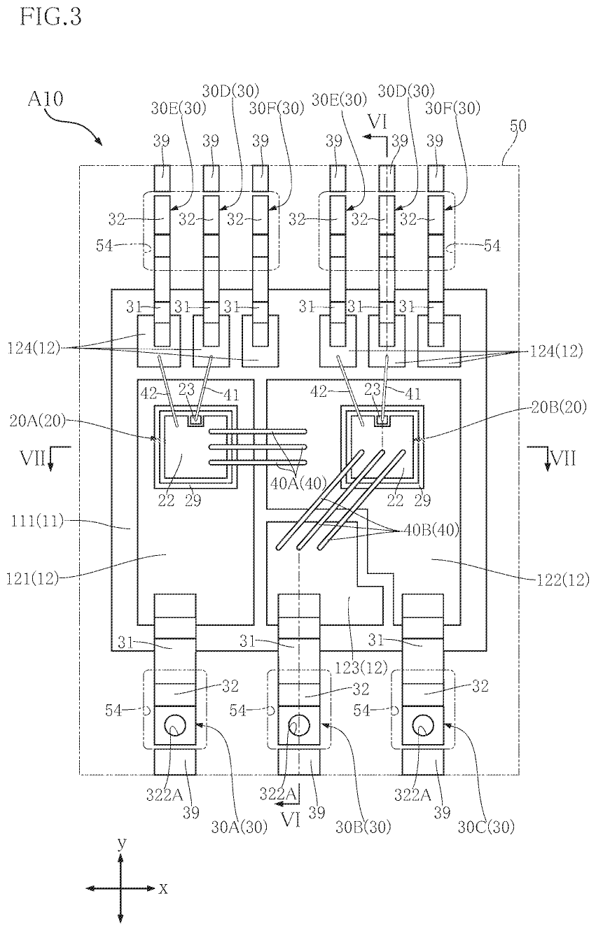

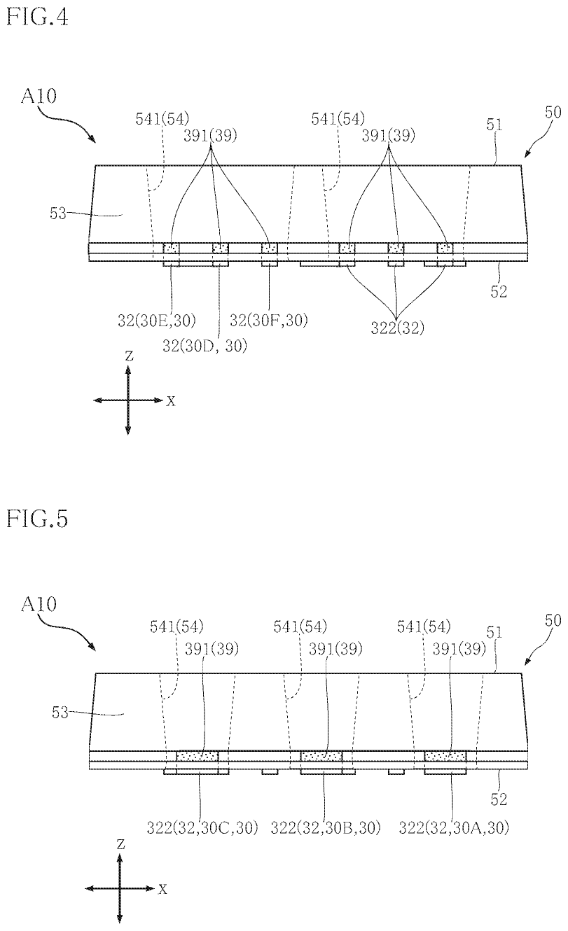

The following describes a semiconductor device A10 according to a first embodiment of the present disclosure, with reference to FIGS. 1 to 9. The semiconductor device A10 may be used in an electronic device including a power conversion circuit, such as an inverter. The semiconductor device A10 includes a support member 11, a plurality of wiring layers 12, two semiconductor elements 20, a plurality of first leads 30, a plurality of second leads 39, two conductive members 40, two gate wires 41, two detection wires 42, and a sealing resin 50. FIG. 3 shows the sealing resin 50 in phantom for convenience of understanding. In FIG. 3, the sealing resin 50 is indicated by an imaginary line (two-dot chain line).

In the description of the semiconductor device A10, the thickness direction of the two semiconductor elements 20 is referred to as “thickness direction z” for convenience. A direction perpendicular to the thickness direction z is referred to as “first direction x”, and the direction perpendicular to both of the thickness direction z and the first direction x is referred to as “second direction y”. As viewed in the thickness direction z (i.e., “in plan view”), the first direction x is parallel to the shorter sides of the semiconductor device A10, and the second direction y is parallel to the longer sides of the semiconductor device A10. However, the present disclosure is not limited to this.

The semiconductor device A10 uses the two semiconductor elements 20 to convert the DC source voltage applied to a first input terminal 30A and a second input terminal 30B (see FIGS. 1 and 3) of the first leads 30 into AC power. The AC power obtained by the conversion is inputted from an output terminal 30C (see FIGS. 1 and 3) of the first leads 30 to a power-supply target such as a motor.

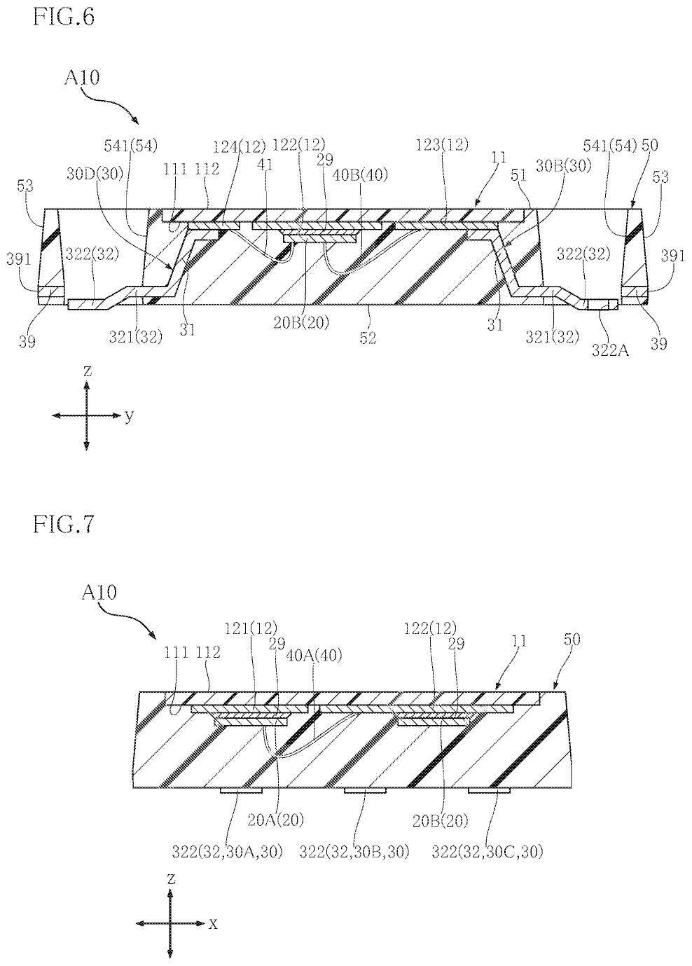

As shown in FIG. 3, the two semiconductor elements 20 are mounted on the support member 11. In the semiconductor device A10, the support member 11 is a single insulating plate. The insulating plate is made of a material containing aluminum nitride (AlN) in its composition. It is preferable that the material have a relatively large heat conductivity. As shown in FIGS. 6 and 7, the support member 11 has a first surface 111 and a second surface 112. The first surface 111 faces in the sense of the thickness direction z in which a bottom surface 52 (described in detail below) of the sealing resin 50 faces. The first surface 111 is in contact with the sealing resin 50. The two semiconductor elements 20 are mounted on the first surface 111. The second surface 112 faces away from the first surface 111 in the thickness direction z. The second surface 112 is exposed from the sealing resin 50.

As shown in FIGS. 3, 6, and 7, the wiring layers 12 are provided on the first surface 111 of the support member 11. The wiring layers 12 are electrically connected to the two semiconductor elements 20. The composition of the wiring layers 12 includes copper (Cu). The wiring layers 12 include a first mounting layer 121, a second mounting layer 122, a relay layer 123, and a plurality of pad layers 124. The first mounting layer 121 is located in a first sense of the first direction x. The second mounting layer 122 is located in a second sense of the first direction x. The first mounting layer 121 and the second mounting layer 122 are adjacent to each other in the first direction x. The relay layer 123 is located between the first mounting layer 121 and the second mounting layer 122 in the first direction x. The pad layers 124 are located opposite from the relay layer 123 with respect to the first mounting layer 121 and the second mounting layer 122 in the second direction y. The pad layers 124 are arranged along the first direction x.

As shown in FIGS. 3 and 7, the two semiconductor elements 20 are individually bonded to the first mounting layer 121 and the second mounting layer 122 of the wiring layers 12 via bonding layers 29. The bonding layers 29 are solder, for example. Alternatively, the bonding layers 29 may be a sintered metal containing silver (Ag), for example. In the semiconductor device A10, each of the two semiconductor elements 20 is an n-channel metal-oxide-semiconductor field-effect transistor (MOSFET) having a vertical structure. Each of the two semiconductor elements 20 includes a compound semiconductor substrate. The main material of the compound semiconductor substrate is silicon carbide (SiC). Alternatively, the main material of the compound semiconductor substrate may be silicon (Si). Furthermore, each of the two semiconductor elements 20 may be another switching element such as an insulated gate bipolar transistor (IGBT). Note that the number of semiconductor elements 20 in the semiconductor device A10 is merely an example, and the number thereof can be freely selected.

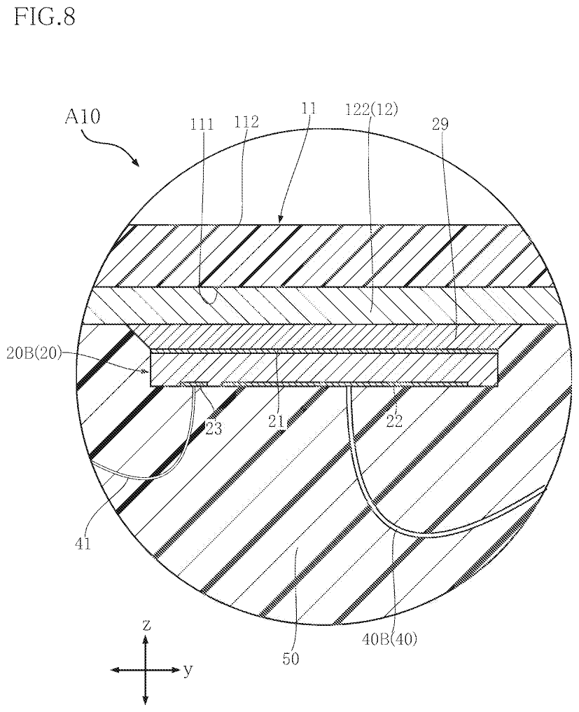

As shown in FIG. 8, each of the two semiconductor elements 20 has a first electrode 21, a second electrode 22, and a gate electrode 23. The first electrode 21 is provided to face the corresponding wiring layer 12. The current that flows through the first electrode 21 corresponds to the electric power that has yet to be converted by the semiconductor element 20. In other words, the first electrode 21 corresponds to a drain electrode.

As shown in FIG. 8, the second electrode 22 is provided on the opposite side from the first electrode 21 in the thickness direction z. The current that flows through the second electrode 22 corresponds to the electric power that has been converted by the semiconductor element 20. In other words, the second electrode 22 corresponds to a source electrode.

As shown in FIG. 8, the gate electrode 23 is provided on the opposite side from the first electrode 21 in the thickness direction z, and is spaced apart from the second electrode 22. A gate voltage is applied to the gate electrode 23 so as to drive the semiconductor element 20. As shown in FIG. 3, the area of the gate electrode 23 is smaller than the area of the second electrode 22 as viewed in the thickness direction z.

As shown in FIGS. 3 and 7, the two semiconductor elements 20 include a first element 20A and a second element 20B. In the semiconductor device A10, the voltage applied to the first element 20A is higher than the voltage applied to the second element 20B. The first electrode 21 of the first element 20A is bonded to the first mounting layer 121 of the wiring layers 12 via the bonding layer 29. As a result, the first electrode 21 of the first element 20A is electrically connected to the first mounting layer 121. The first electrode 21 of the second element 20B is bonded to the second mounting layer 122 of the wiring layers 12 via the bonding layer 29. As a result, the first electrode 21 of the second element 20B is electrically connected to the second mounting layer 122.

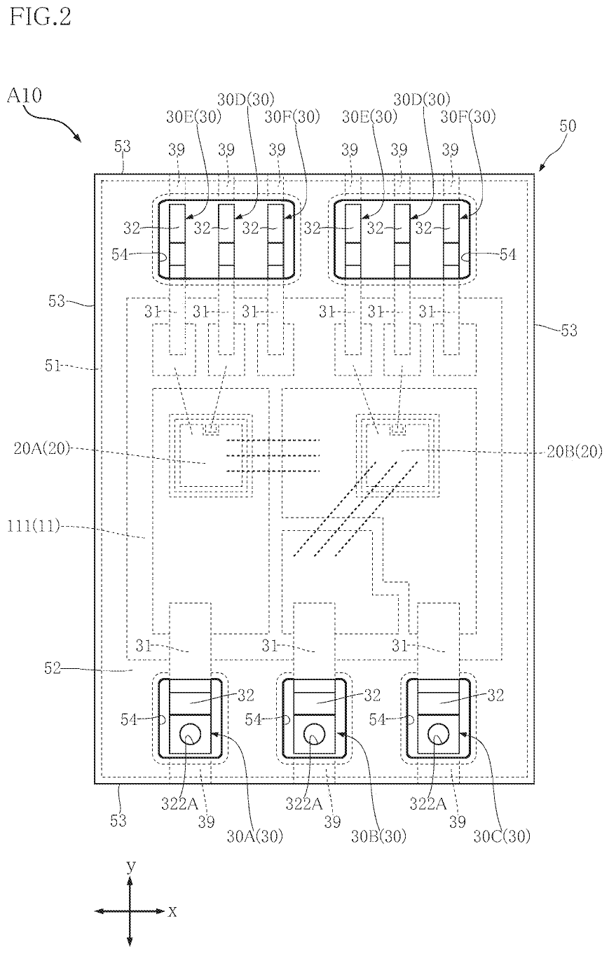

As shown in FIG. 3, the first leads 30 are individually bonded to the wiring layers 12. As a result, the first leads 30 are electrically connected to the wiring layers 12. As viewed in the thickness direction z, the first leads 30 overlap with the support member 11. As viewed in the thickness direction z, the first leads 30 extend along the second direction y. The first leads 30 are formed from the same lead frame. The composition of the first leads 30 includes copper. As shown in FIGS. 2, 3, and 6, each of the first leads 30 has a covered portion 31 and an exposed portion 32.

As shown in FIGS. 2 and 6, the covered portion 31 is covered with the sealing resin 50. As shown in FIG. 3, a first side of the covered portion 31 in the second direction y (the side closer to the two semiconductor elements 20) is bonded to one of the wiring layers 12. As viewed in the first direction x, the covered portion 31 includes a section inclined relative to the first surface 111 of the support member 11.

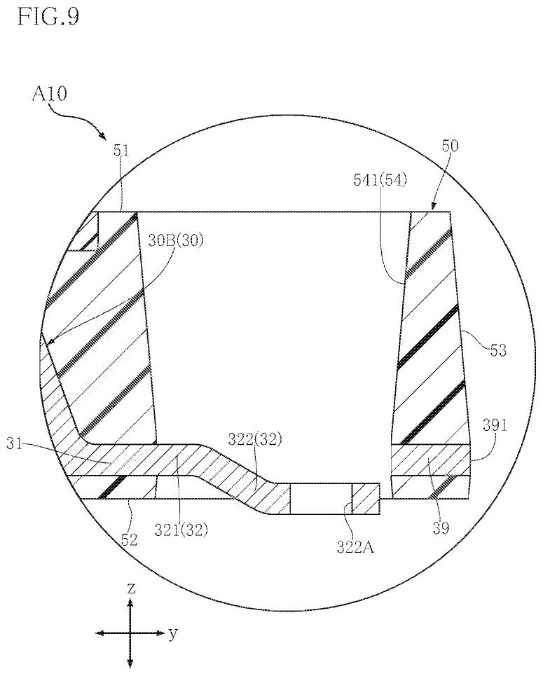

As shown in FIGS. 2 and 6, the exposed portion 32 is connected to the covered portion 31 and exposed from the sealing resin 50. As shown in FIGS. 6 and 9, the exposed portion 32 has a base 321 and a mount 322. The base 321 is connected to the covered portion 31. As viewed in the first direction x, the base 321 extends along the second direction y. The mount 322 is connected to the base 321, and is located opposite from the covered portion 31 with respect to the base 321 in the second direction y. When the semiconductor device A10 is mounted on a wiring board, solder is adhered to the mount 322. The mount 322 is bent from the base 321 in the sense of the thickness direction z in which the bottom surface 52 (described in detail below) of the sealing resin 50 faces. At least a part of the mount 322 protrudes from the bottom surface 52 in the thickness direction z.

As shown in FIGS. 1 to 3, the first leads 30 include the first input terminal 30A, the second input terminal 30B, the output terminal 30C, two gate terminals 30D, two detection terminals 30E, and two dummy terminals 30F. The first leads 30, except for the two dummy terminals 30F, are electrically connected to the two semiconductor elements 20 via the wiring layers 12. The first input terminal 30A, the second input terminal 30B, and the output terminal 30C are located in a first sense of the second direction y and arranged along the first direction x. The two gate terminals 30D, the two detection terminals 30E, and the two dummy terminals 30F are located in a second sense of the second direction y and arranged along the first direction x. Each of the first input terminal 30A, the second input terminal 30B, and the output terminal 30C is wider than any of the other first leads 30.

As shown in FIG. 3, the covered portion 31 of the first input terminal 30A is bonded to the first mounting layer 121 of the wiring layers 12. As a result, the first input terminal 30A is electrically connected to the first electrode 21 of the first element 20A. The covered portion 31 of the output terminal 30C is bonded to the second mounting layer 122 of the wiring layers 12. As a result, the output terminal 30C is electrically connected to the first electrode 21 of the second element 20B. The covered portion 31 of the second input terminal 30B is bonded to the relay layer 123 of the wiring layers 12.

As shown in FIG. 3, the covered portions 31 of the two gate terminals 30D are individually bonded to two of the pad layers 124 of the wiring layers 12. The two detection terminals 30E are bonded to two of the pad layers 124 of the wiring layers 12. A gate voltage is applied to each of the gate terminals 30D so as to drive the two semiconductor elements 20. Each of the two detection terminals 30E is positioned next to one of the two gate terminals 30D. A voltage corresponding to the current flowing through each of the second electrodes 22 of the two semiconductor elements 20 is applied to each of the two detection terminals 30E. The two dummy terminals 30F are bonded to two of the pad layers 124 of the wiring layers 12. In the first direction x, each of the two dummy terminals 30F is located opposite, with respect to a corresponding one of the two gate terminals 30D, from one of the two detection terminals 30E that is adjacent to the corresponding gate terminal 30D.

As shown in FIGS. 1, 2, and 9, the exposed portion 32 of each of the first input terminal 30A, the second input terminal 30B, and the output terminal 30C of the first leads 30 has a hole 322A. The hole 322A penetrates through the mount 322 in the thickness direction z.

As shown in FIGS. 1 and 2, as viewed in the thickness direction z, the second leads 39 are located opposite from the covered portions 31 of the first leads 30 with respect to the exposed portions 32 of the first leads 30. As shown in FIGS. 6 and 9, each of the second leads 39 is sandwiched by the sealing resin 50 in the thickness direction z. As viewed in the first direction x, the second leads 39 extend along the second direction y. The second leads 39 are formed from the same lead frame from which the first leads 30 are formed. Accordingly, the second leads 39 include the same composition as the first leads 30. Each of the second leads 39 has an end surface 391. The end surface 391 faces in a direction perpendicular to the thickness direction z (the second direction y in the semiconductor device A10). The second leads 39 are remnants resulting from cutting off the semiconductor device A10 from the lead frame during the manufacturing of the semiconductor device A10. The end surface 391 corresponds to a cut surface formed when the semiconductor device A10 is cut off from the lead frame.

As shown in FIG. 9, the second leads 39 in the semiconductor device A10 are spaced apart from the first leads 30. The exposed portions 32 of the first leads 30 are individually connected to the second leads 39 until a step of forming the sealing resin 50 in the manufacturing process of the semiconductor device A10. After the sealing resin 50 is formed, the mounts 322 of the exposed portions 32 of the first leads 30 are formed by bending. At this point, the second leads 39 are cut off from the exposed portions 32 of the first leads 30. The second leads 39 are in an electrically floating state unlike the first leads 30.

As shown in FIG. 3, the two conductive members 40 are bonded to the two semiconductor elements 20, and to the second mounting layer 122 and the relay layer 123 of the wiring layers 12. The two conductive members 40 include a first member 40A and a second member 40B. Each of the first member 40A and the second member 40B is composed of a plurality of wires. The composition of the wires includes aluminum (Al). Alternatively, the composition of the wires may include copper. Each of the first member 40A and the second member 40B may be a metal clip instead of the wires.

As shown in FIG. 3, the first member 40A is bonded to the second electrode 22 of the first element 20A, and to the second mounting layer 122 of the wiring layers 12. As a result, the second electrode 22 of the first element 20A is electrically connected to the second mounting layer 122, and to the first electrode 21 of the second element 20B. As shown in FIG. 3, the second member 40B is bonded to the second electrode 22 of the second element 20B, and to the relay layer 123 of the wiring layers 12. As a result, the second electrode 22 of the second element 20B is electrically connected to the second input terminal via the relay layer 123.

As shown in FIG. 3, the two gate wires 41 are bonded to the gate electrodes 23 of the two semiconductor elements 20, and to the two pad layers 124 of the wiring layers 12 to which the two gate terminals 30D are bonded. As a result, the two gate terminals 30D are individually and electrically connected to the gate electrodes 23 of the two semiconductor elements 20. The composition of the two gate wires 41 includes gold (Au).

As shown in FIG. 3, the two detection wires 42 are bonded to the second electrodes 22 of the two semiconductor elements 20, and to the two pad layers 124 of the wiring layers 12 to which the two detection terminals 30E are bonded. As a result, the two detection terminals 30E are individually and electrically connected to the second electrodes 22 of the two semiconductor elements 20. The composition of the two detection wires 42 includes gold (Au).

As shown in FIGS. 2 and 6, the sealing resin 50 covers the two semiconductor elements 20, and a portion of each of the first leads 30. Furthermore, the sealing resin 50 covers the wiring layers 12, the two conductive members 40, the two gate wires 41, and the two detection wires 42. The sealing resin 50 is electrically insulative. The sealing resin 50 is made of a material containing black epoxy resin, for example. As shown in FIGS. 1 and 2, the sealing resin 50 has a top surface 51, a bottom surface 52, a plurality of side surfaces 53, and a plurality of openings 54.

As shown in FIGS. 4 to 7, the top surface 51 and the bottom surface 52 face away from each other in the thickness direction z. The bottom surface 52 faces in the sense of the thickness direction z in which the first surface 111 of the support member 11 faces. The second surface 112 of the support member 11 is exposed from the top surface 51.

As shown in FIGS. 1, 2, 4, and 5, the side surfaces 53 are connected to the top surface 51 and the bottom surface 52. The side surfaces 53 include a pair of side surfaces 53 spaced apart from each other in the first direction x, and a pair of side surfaces 53 spaced apart from each other in the second direction y. The end surfaces 391 of the second leads 39 are exposed from the pair of side surfaces 53 spaced apart from each other in the second direction y.

As shown in FIGS. 1, 2, and 6, the openings 54 extend from the top surface 51 to the bottom surface 52. In the semiconductor device A10, each of the openings 54 has a closed shape as viewed in the thickness direction z. Accordingly, each of the openings 54 has an inner peripheral surface 541 facing in a direction perpendicular to the thickness direction z. The inner peripheral surface 541 is connected to the top surface 51 and the bottom surface 52. As viewed in the thickness direction z, the inner peripheral surface 541 surrounds the exposed portion 32 of the first lead 30 housed in the corresponding opening 54.

As shown in FIGS. 1 and 2, as viewed in the thickness direction z, at least one of the exposed portions 32 of the first leads 30 is housed in one of the openings 54. In the case of the semiconductor device A10, all of the exposed portions 32 of the first leads 30 are housed in the openings 54, as viewed in the thickness direction z. Specifically, the exposed portions 32 of the first input terminal 30A, the second input terminal 30B, and the output terminal 30C of the first leads 30 are housed in the respective openings 54. The first leads 30 include groups that are each made up of a gate terminal 30D, a detection terminal 30E, and a dummy terminal 30F, and the exposed portions 32 of the first leads 30 in each group are housed in one of the openings 54.

As shown in FIG. 9, the cross-sectional area of each of the openings 54 with respect to the thickness direction z gradually decreases from the top surface 51 to the exposed portion 32 of one of the first leads 30 housed in the opening 54.

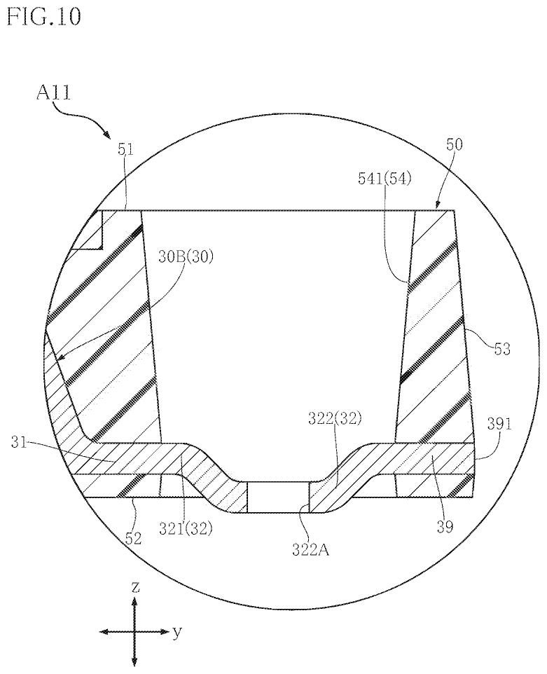

Next, a semiconductor device A11, which is a first variation of the semiconductor device A10, will be described with reference to FIG. 10. The cross-sectional position in FIG. 10 is the same as the cross-sectional position in FIG. 9.

As shown in FIG. 10, the semiconductor device A11 is different from the semiconductor device A10 in the configurations of the exposed portions 32 of the first leads 30 and the second leads 39. In the semiconductor device A11, the second leads 39 are individually connected to the mounts 322 of the exposed portions 32 of the first leads 30. As a result, the second leads 39 are individually and electrically connected to the first leads 30.

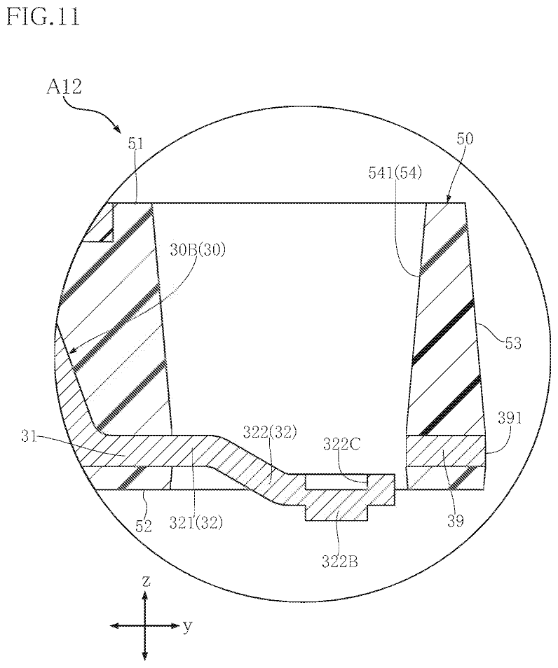

Next, a semiconductor device A12, which is a second variation of the semiconductor device A10, will be described with reference to FIG. 11. The cross-sectional position in FIG. 11 is the same as the cross-sectional position in FIG. 9.

As shown in FIG. 11, the semiconductor device A12 is different from the semiconductor device A10 in the configuration of the exposed portions 32 of the first leads 30. In the semiconductor device A12, the exposed portion 32 of each of the first leads 30 has a protrusion 322B and a recess 322C. The protrusion 322B protrudes from the mount 322 of the exposed portion 32 in the sense of the thickness direction z in which the bottom surface 52 of the sealing resin 50 faces. The recess 322C is located opposite from the protrusion 322B with respect to the mount 322 in the thickness direction z, and is recessed from the mount 322 in the thickness direction z. As viewed in the thickness direction z, the recess 322C overlaps with the protrusion 322B.

Next, advantages of the semiconductor device A10 will be described.

The semiconductor device A10 includes the first leads 30 electrically connected to the semiconductor elements 20, and the sealing resin 50 covering a portion of each of the first leads 30. The sealing resin 50 has the openings 54 extending from the top surface 51 to the bottom surface 52. Each of the first leads 30 has a covered portion 31 covered with the sealing resin 50, and an exposed portion 32 connected to the covered portion 31 and exposed from the sealing resin 50. As viewed in the thickness direction z, at least one of the exposed portions 32 of the first leads 30 is housed in one of the openings 54. This increases the surface area of the sealing resin 50, resulting in an increase in the creepage distance from a first lead 30 having an exposed portion 32 housed in an opening 54 to another first lead 30 having an exposed portion 32 not housed in the opening 54. As such, the semiconductor device A10 can be more compact while suppressing a decrease in the dielectric strength.

In the semiconductor device A10, each of the openings 54 of the sealing resin 50 has a closed shape as viewed in the thickness direction z. This further increases the surface area of the sealing resin 50, resulting in a further increase in the creepage distance from a first lead 30 having an exposed portion 32 housed in an opening 54 to another first lead 30 having an exposed portion 32 not housed in the opening 54. As a result, a decrease in the dielectric strength of the semiconductor device A10 can be effectively suppressed. Furthermore, in the semiconductor device A10, all of the exposed portions 32 of the first leads 30 are housed in the openings 54, as viewed in the thickness direction z. This improves the effect of suppressing a decrease in the dielectric strength of the semiconductor device A10.

The exposed portion 32 of each of the first leads 30 has a base 321 connected to a covered portion 31, and a mount 322 extending from the base 321 in a manner bending with respect to the bottom surface 52 of the sealing resin 50. At least a part of the mount 322 protrudes from the bottom surface 52 in the thickness direction z. In this way, when the semiconductor device A10 is mounted on a wiring board, the mounts 322 can be pressed more firmly against the wiring board. This makes it possible to improve the bonding strength of the first leads 30 to the wiring board. Furthermore, since the mounts 322 function as flexible dampers, the mounts 322 can reduce vibrations transmitted from the outside to the semiconductor device A10.

The semiconductor device A10 further includes the second leads 39. Each of the second leads 39 is sandwiched by the sealing resin 50 in the first direction x. The second leads 39 include the end surfaces 391 facing in a direction perpendicular to the thickness direction z (the second direction y in the semiconductor device A10) and exposed from the sealing resin 50. In this case, the second leads 39 are spaced apart from the first leads 30. With this configuration, the mounts 322 of the exposed portions 32 of the first leads 30 can be formed to have a more desirable shape during the manufacturing of the semiconductor device A10. Furthermore, the second leads 39 are in an electrically floating state. As such, the second leads 39 do not constitute a factor of a decrease in the dielectric strength of the semiconductor device A10.

At least one of the exposed portions 32 of the first leads 30 has a hole 322A that penetrates through in the thickness direction z. This makes it possible to visually check the adherence state of solder to the exposed portion 32 when the semiconductor device A10 is mounted on the wiring board. Furthermore, as the solder enters into the hole 322A, the bonding strength of the first lead 30 to the wiring board can be improved.

As for the semiconductor device A12, the exposed portion 32 of each of the first leads 30 has a protrusion 322B. The protrusion 322B protrudes from the mount 322 of the exposed portion 32 in the sense of the thickness direction z in which the bottom surface 52 of the sealing resin 50 faces. As a result, when the semiconductor device A10 is mounted on the wiring board, solder having a predetermined thickness enters between the wiring board and the mount 322, and the exposed portion 32 exhibits an anchoring effect to the solder. This further improves the bonding strength of the first leads 30 to the wiring board.

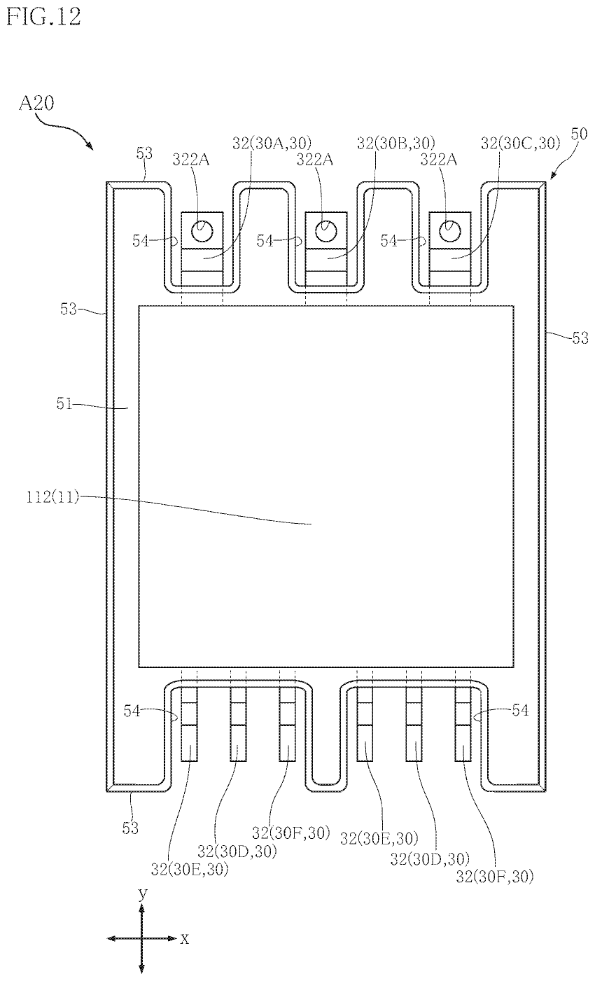

The following describes a semiconductor device A20 according to a second embodiment of the present disclosure, with reference to FIGS. 12 to 16. In these figures, elements that are the same as or similar to the elements of the semiconductor device A10 described above are provided with the same reference signs, and descriptions thereof are omitted.

The semiconductor device A20 is different from the semiconductor device A10 in the configurations of the first leads 30 and the sealing resin 50. Furthermore, the semiconductor device A20 does not include the second leads 39.

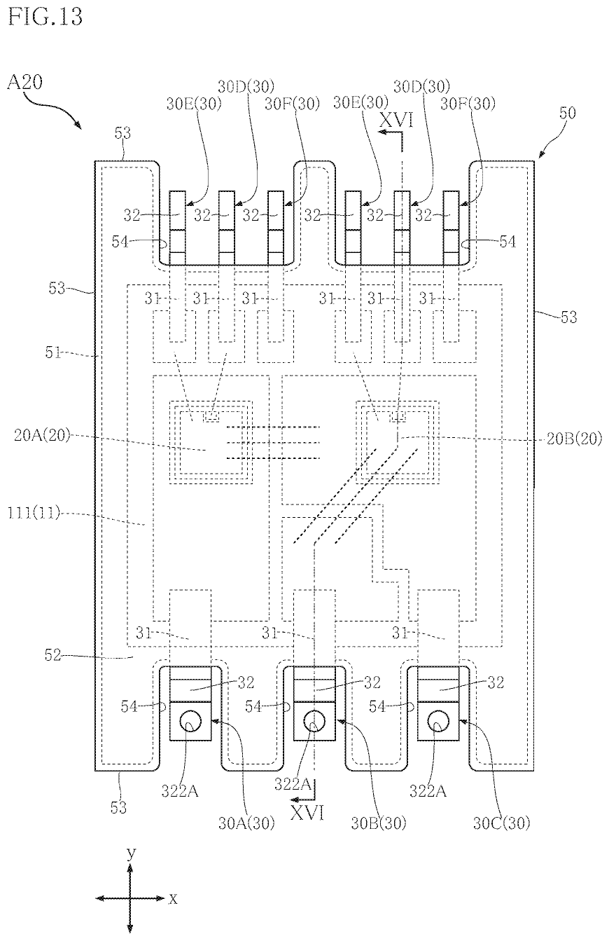

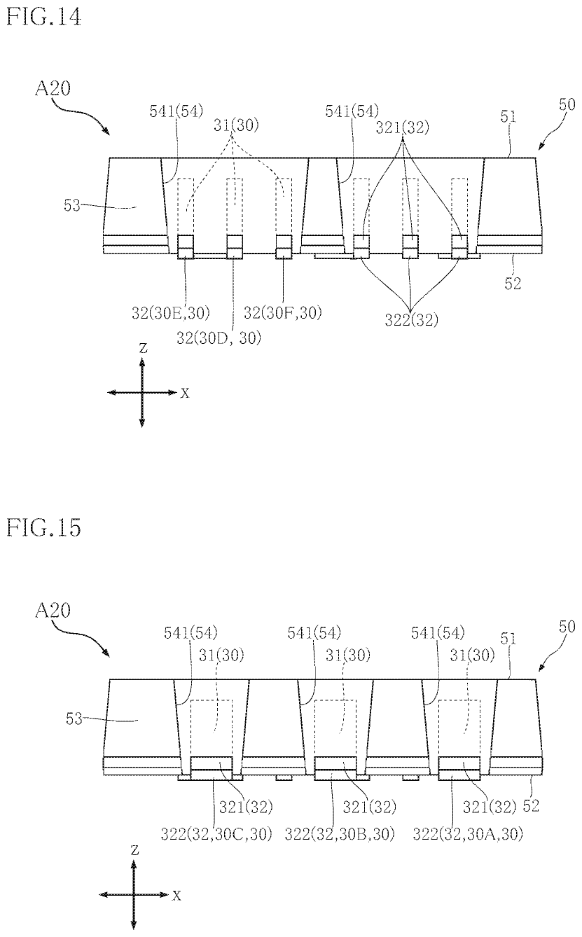

As shown in FIGS. 12 and 13, in the semiconductor device A20, the openings 54 of the sealing resin 50 are recessed from a pair of side surfaces 53, which are included in the plurality of side surfaces 53 and spaced apart from each other in the second direction y. Accordingly, as shown in FIGS. 14 and 15, the exposed portions 32 of the first leads 30 are exposed from the openings 54 and the side surfaces 53.

As shown in FIGS. 12 and 13, in the semiconductor device A20, all of the exposed portions 32 of the first leads 30 are also similarly housed in the openings 54 of the sealing resin 50, as viewed in the thickness direction z. Specifically, the exposed portions 32 of the first input terminal 30A, the second input terminal 30B, and the output terminal 30C of the first leads 30 are housed in the respective openings 54. The first leads 30 include groups that are each made up of a gate terminal 30D, a detection terminal 30E, and a dummy terminal 30F, and the exposed portions 32 of the first leads 30 in each of the groups are housed in one of the openings 54.

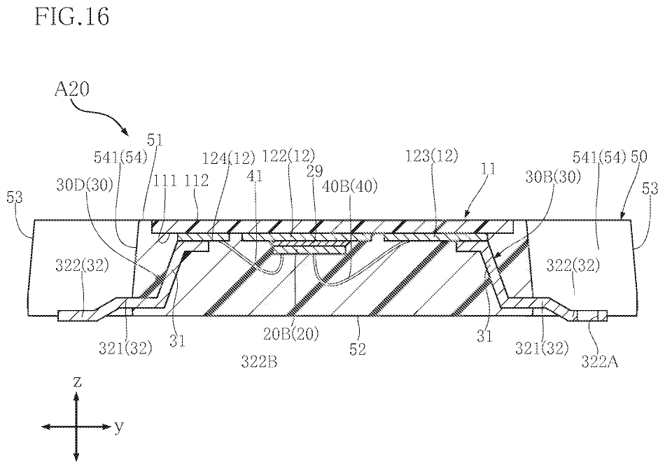

As shown in FIG. 16, in the semiconductor device A20, at least a portion of the mount 322 of the exposed portion 32 of each of the first leads 30 also similarly protrudes from the bottom surface 52 of the sealing resin 50 in the thickness direction z.

Next, advantages of the semiconductor device A20 will be described.

The semiconductor device A20 includes the first leads 30 electrically connected to the semiconductor elements 20, and the sealing resin 50 covering a portion of each of the first leads 30. The sealing resin 50 has the openings 54 extending from the top surface 51 to the bottom surface 52. Each of the first leads 30 has a covered portion 31 covered with the sealing resin 50, and an exposed portion 32 connected to the covered portion 31 and exposed from the sealing resin 50. As viewed in the thickness direction z, at least one of the exposed portions 32 of the first leads 30 is housed in one of the openings 54. As such, the semiconductor device A20 can also be more compact while suppressing a decrease in the dielectric strength.

In the semiconductor device A20, all of the exposed portions 32 of the first leads 30 are also similarly housed in the openings 54 of the sealing resin 50, as viewed in the thickness direction z. This improves the effect of suppressing a decrease in the dielectric strength of the semiconductor device A20. Furthermore, the semiconductor device A20 has configurations similar to the semiconductor device A10, whereby the semiconductor device A20 also has advantages owing to the configurations.

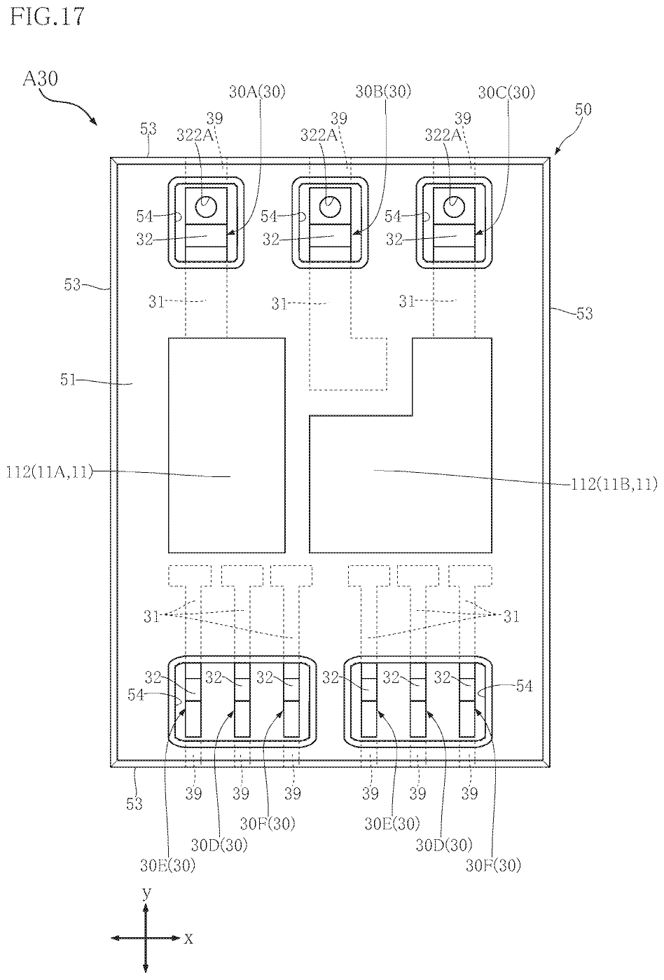

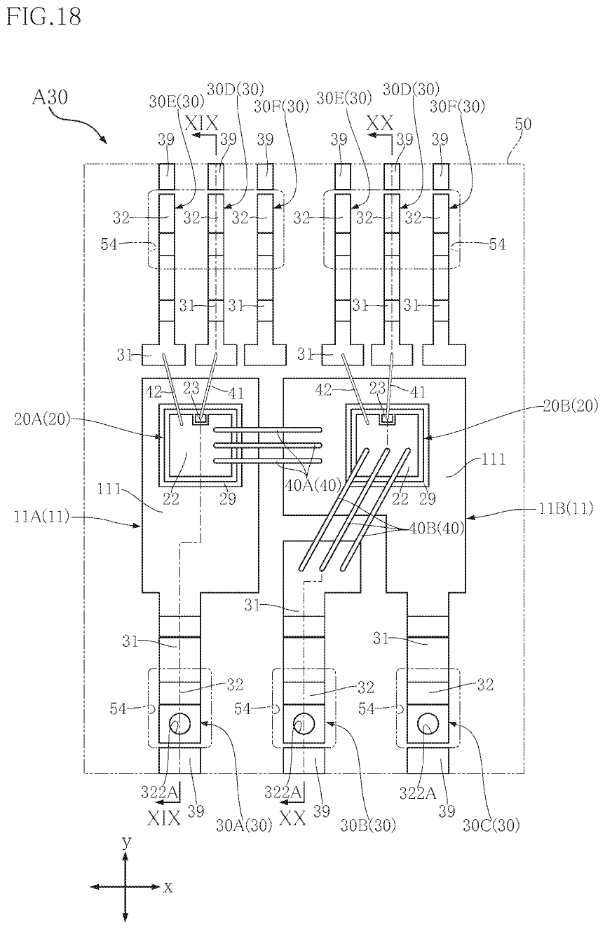

The following describes a semiconductor device A30 according to a third embodiment of the present disclosure, with reference to FIGS. 17 to 20. In these figures, elements that are the same as or similar to the elements of the semiconductor device A10 described above are provided with the same reference signs, and descriptions thereof are omitted. FIG. 18 shows the sealing resin 50 in phantom for convenience of understanding. In FIG. 18, the sealing resin 50 is indicated by an imaginary line.

The semiconductor device A30 is different from the semiconductor device A10 in the configurations of the support member 11, the two semiconductor elements 20, the first leads 30, the two conductive members 40, the two gate wires 41, and the two detection wires 42. Furthermore, the semiconductor device A30 does not include the wiring layers 12.

As shown in FIGS. 17 and 18, the support member 11 of the semiconductor device A30 includes a first die pad 11A and a second die pad 11B that are spaced apart from each other. The first die pad 11A and the second die pad 11B are metal conductive plates. The first die pad 11A and the second die pad 11B are formed from the same lead frame from which the first leads 30 and the second leads 39 are formed. Accordingly, the first die pad 11A and the second die pad 11B include the same composition as the first leads 30. Each of the first die pad 11A and the second die pad 11B is thicker than each of the first leads 30. The second surface 112 of each of the first die pad 11A and the second die pad 11B is exposed from the top surface 51 of the sealing resin 50.

As shown in FIGS. 18 and 19, the first element 20A of the two semiconductor elements 20 is mounted on the first surface 111 of the first die pad 11A. The first electrode 21 of the first element 20A is bonded to the first surface 111 of the first die pad 11A via the bonding layer 29. As a result, the first electrode 21 of the first element 20A is electrically connected to the first die pad 11A. As shown in FIGS. 18 and 19, the second element 20B of the two semiconductor elements 20 is mounted on the first surface 111 of the second die pad 11B. The first electrode 21 of the second element 20B is bonded to the first surface 111 of the second die pad 11B via the bonding layer 29. As a result, the first electrode 21 of the second element 20B is electrically connected to the second die pad 11B.

As shown in FIGS. 18 and 19, the covered portion 31 of the first input terminal 30A of the first leads 30 is connected to the first die pad 11A. As a result, the first input terminal 30A is electrically connected to the first die pad 11A. As shown in FIG. 18, the covered portion 31 of the output terminal 30C of the first leads 30 is connected to the second die pad 11B. As a result, the output terminal 30C is electrically connected to the second die pad 11B. The first leads 30, except for the first input terminal 30A and the output terminal 30C, are located away from the support member 11 as viewed in the thickness direction z.

As shown in FIG. 18, the first member 40A of the two conductive members 40 is bonded to the second electrode 22 of the first element 20A, and to the first surface 111 of the second die pad 11B. As a result, the second electrode 22 of the first element 20A is electrically connected to the second die pad 11B. As shown in FIGS. 18 and 20, the second member 40B of the two conductive members 40 is bonded to the second electrode 22 of the second element 20B, and to the covered portion 31 of the second input terminal 30B of the first leads 30. As a result, the second electrode 22 of the second element 20B is electrically connected to the second input terminal 30B.

As shown in FIG. 18, the two gate wires 41 are individually bonded to the gate electrodes 23 of the two semiconductor elements 20, and to the two gate terminals 30D of the first leads 30. As a result, the two gate terminals 30D are individually and electrically connected to the gate electrodes 23 of the two semiconductor elements 20. As shown in FIG. 18, the two detection wires 42 are individually and electrically connected to the second electrodes 22 of the two semiconductor elements 20, and to the two detection terminals 30E of the first leads 30. As a result, the two detection terminals 30E are individually and electrically connected to the second electrodes 22 of the two semiconductor elements 20.

Next, advantages of the semiconductor device A30 will be described.

The semiconductor device A30 includes the first leads 30 electrically connected to the semiconductor elements 20, and the sealing resin 50 covering a portion of each of the first leads 30. The sealing resin 50 has the openings 54 extending from the top surface 51 to the bottom surface 52. Each of the first leads 30 has a covered portion 31 covered with the sealing resin 50, and an exposed portion 32 connected to the covered portion 31 and exposed from the sealing resin 50. As viewed in the thickness direction z, at least one of the exposed portions 32 of the first leads 30 is housed in one of the openings 54. As such, the semiconductor device A30 can also be more compact while suppressing a decrease in the dielectric strength.

In the semiconductor device A30, all of the exposed portions 32 of the first leads 30 are also similarly housed in the openings 54 of the sealing resin 50, as viewed in the thickness direction z. This makes it possible to effectively suppress a decrease in the dielectric strength of the semiconductor device A30. Furthermore, the semiconductor device A30 has configurations similar to the semiconductor device A10, whereby the semiconductor device A30 also has advantages owing to the configurations.

In the semiconductor device A30, the support member 11 includes a conductive plate (at least one of the first die pad 11A and the second die pad 11B). At least one of the first leads 30 is connected to the support member 11. The semiconductor elements 20 are bonded to the first surface 111 of the support member 11. The semiconductor device A30 further includes the conductive member 40 (second member 40B) bonded to one of the semiconductor elements 20 and any of the first leads 30. This eliminates the need of the wiring layers 12 in the semiconductor device A30.

In the semiconductor device A30, the second surface 112 of the support member 11 is also similarly exposed from the top surface 51 of the sealing resin 50. Furthermore, the support member 11 in the semiconductor device A30 is made of a conductive plate, whereas the support member 11 in the semiconductor device A10 is made of an insulating plate. As such, the heat conductivity of the former support member 11 is greater than that of the latter support member 11. This further improves the heat dissipation of the semiconductor device A30. In this case, when the support member 11 is thicker than each of the first leads 30, heat is more likely to be transmitted in the in-plane direction (the first direction x and the second direction y) of the support member 11, which is suitable for the improvement of the heat dissipation of the semiconductor device A30. Furthermore, since the covered portions 31 of the first leads 30 connected to the support member 11 are sandwiched by the sealing resin 50 in the thickness direction z, the support member 11 is prevented from falling off the top surface 51 of the sealing resin 50.

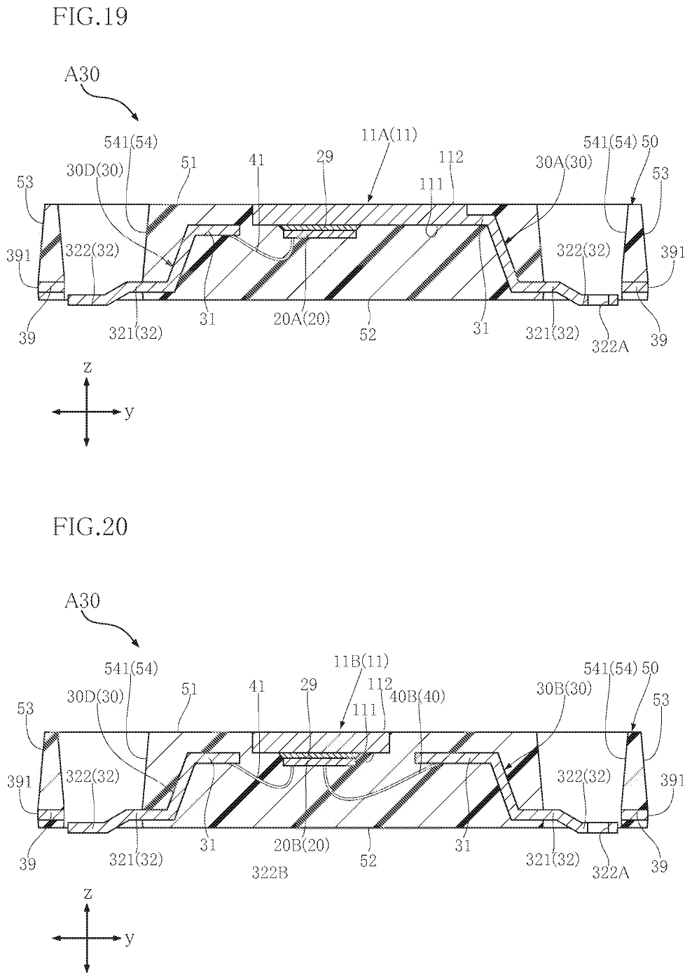

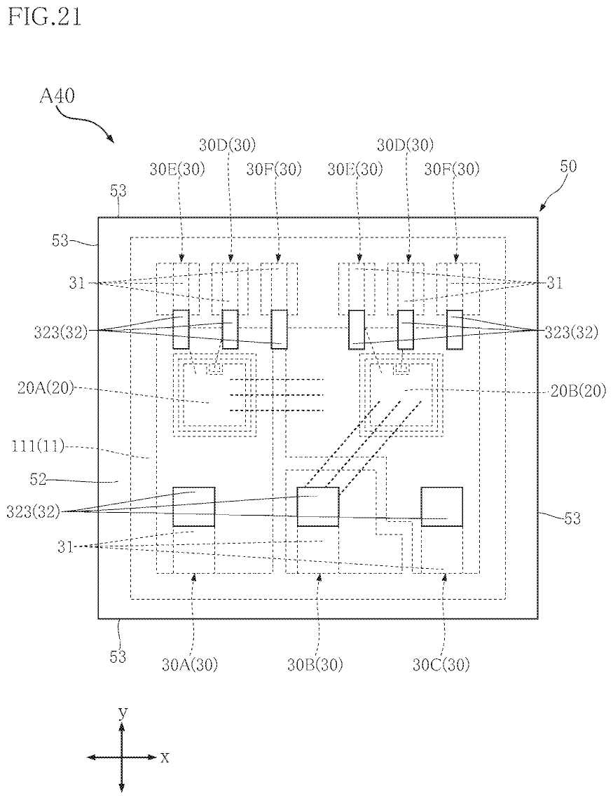

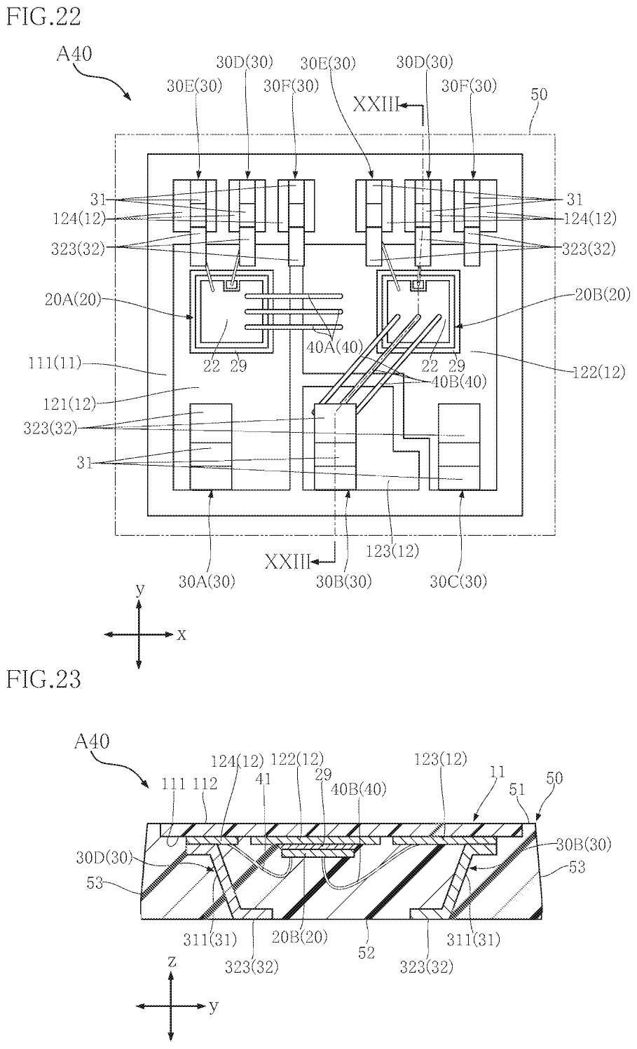

The following describes a semiconductor device A40 according to a fourth embodiment of the present disclosure, with reference to FIGS. 21 to 23. In these figures, elements that are the same as or similar to the elements of the semiconductor device A10 described above are provided with the same reference signs, and descriptions thereof are omitted. FIG. 22 shows the sealing resin in phantom for convenience of understanding. In FIG. 22, the sealing resin 50 is indicated by an imaginary line.

The semiconductor device A40 is different from the semiconductor device A10 in the configurations of the first leads 30 and the sealing resin 50. Furthermore, the semiconductor device A40 does not include the second leads 39.

As shown in FIG. 21, the sealing resin 50 of the semiconductor device A40 is not formed with the openings 54. As shown in FIGS. 21 and 23, at least one of the exposed portions 32 of the first leads 30 has a mounting surface 323. In the semiconductor device A40, all of the exposed portions 32 of the first leads 30 have mounting surfaces 323. The mounting surfaces 323 are exposed from the bottom surface 52 of the sealing resin 50. The first leads 30 having the mounting surfaces 323 are covered with the sealing resin 50 except for the mounting surface 323. When the semiconductor device A40 is mounted on a wiring board, solder is adhered to the entire mounting surfaces 323. The mounting surfaces 323 are surrounded by the bottom surface 52. The mounting surfaces 323 are flush with the bottom surface 52.

As shown in FIG. 23, the covered portion 31 of each of the first leads 30 having the mounting surfaces 323 has an inclined surface 311. The inclined surface 311 is connected to the mounting surface 323, and is inclined relative to the bottom surface 52 of the sealing resin 50. The inclined surface 311 is in contact with the sealing resin 50. As viewed in the thickness direction z, the mounting surface 323 is located farther away from a peripheral edge of the bottom surface 52 than is the inclined surface 311 in the second direction y.

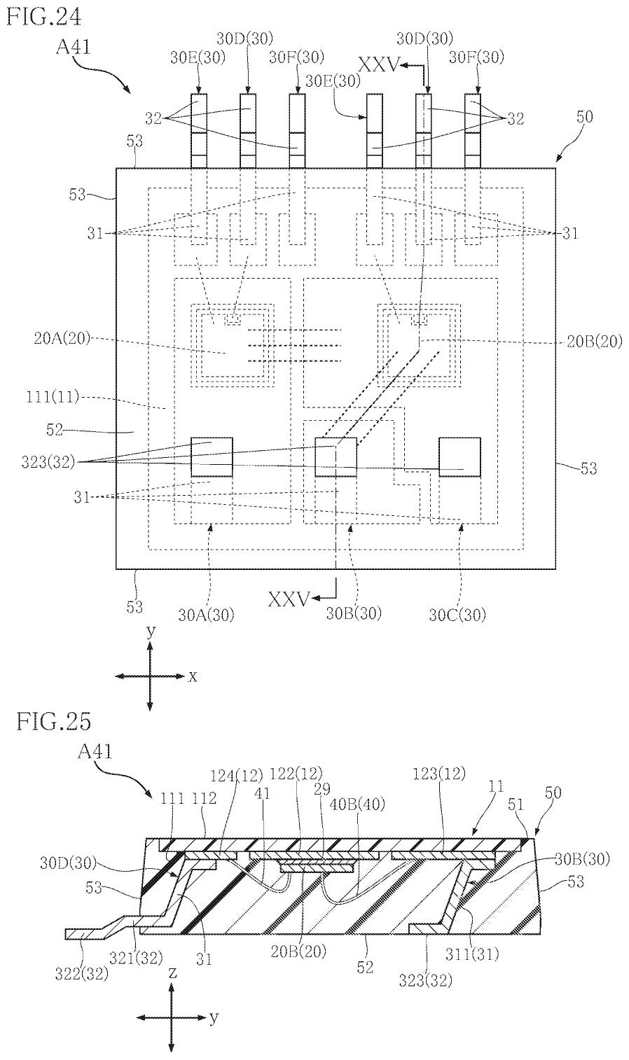

Next, a semiconductor device A41, which is a variation of the semiconductor device A40, will be described with reference to FIGS. 24 and 25.

As shown in FIG. 24, the semiconductor device A41 is different from the semiconductor device A10 in the configuration of the first leads 30. In the semiconductor device A41, the exposed portion 32 of each of the two gate terminals 30D, the two detection terminals 30E, and the two dummy terminals 30F of the first leads 30 does not have a mounting surface 323. The configuration of these first leads 30 is the same as that of the corresponding first leads 30 in the semiconductor device A10. Accordingly, as shown in FIG. 25, at least a portion of the mount 322 of the exposed portion 32 of each of these first leads 30 protrudes from the bottom surface 52 of the sealing resin 50 in the thickness direction z.

Next, advantages of the semiconductor device A40 will be described.

The semiconductor device A40 includes the first leads 30 electrically connected to the semiconductor elements 20, and the sealing resin 50 covering a portion of each of the first leads 30. The sealing resin 50 has the bottom surface 52 facing in the thickness direction z. At least one of the first leads 30 has a mounting surface 323 exposed from and surrounded by the bottom surface 52. This increases the creepage distance from a first lead 30 having a mounting surface 323 to a first lead 30 not having a mounting surface 323. Furthermore, when the semiconductor device A40 is mounted on a wiring board, solder is adhered to the entire mounting surface 323, thereby rendering the creepage distance between two first leads 30 with the mounting surfaces 323 practically infinite. As such, the semiconductor device A40 can also be more compact while suppressing a decrease in the dielectric strength. Furthermore, the semiconductor device A40 has configurations similar to the semiconductor device A10, whereby the semiconductor device A40 also has advantages owing to the configurations.

It is preferable that at least one of the first input terminal 30A and the second input terminal 30B of the first leads 30 have a mounting surface 323. A higher voltage is applied to each of the first input terminal 30A and the second input terminal than to each of the other first leads 30. As such, increasing the creepage distance between the first input terminal 30A and the second input terminal 30B can effectively suppress a decrease in the dielectric strength of the semiconductor device A40.

In the semiconductor device A40, all of the exposed portions 32 of the first leads 30 have the mounting surfaces 323. This makes it possible to effectively suppress a decrease in the dielectric strength of the semiconductor device A40.

Of the plurality of first leads 30, the covered portion 31 of each first lead 30 having a mounting surface 323 has an inclined surface 311. The inclined surface 311 is in contact with the sealing resin 50. This prevents the first lead 30 from falling off the bottom surface 52 of the sealing resin 50. Furthermore, as viewed in the thickness direction z, the mounting surface 323 is located farther away from a peripheral edge of the bottom surface 52 than is the inclined surface 311. This makes it possible to reduce the size of the semiconductor device A40 in a direction (the second direction y in the semiconductor device A40) corresponding to the direction in which the mounting surface 323 is farther away from a peripheral edge of the bottom surface 52 than is the inclined surface 311.

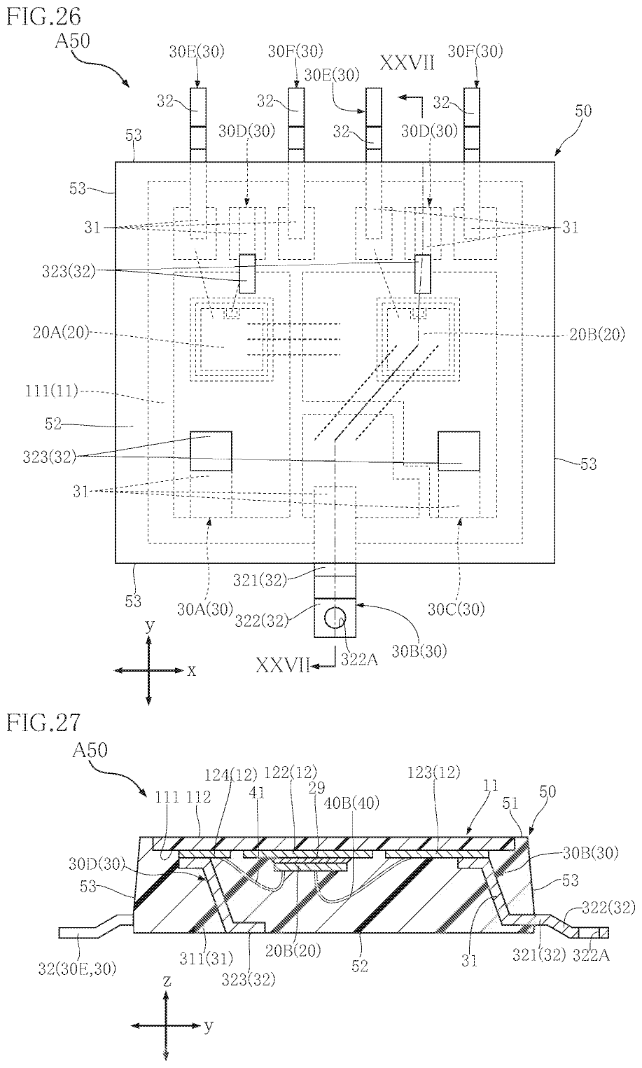

The following describes a semiconductor device A50 according to a fifth embodiment of the present disclosure, with reference to FIGS. 26 and 27. In these figures, elements that are the same as or similar to the elements of the semiconductor device A10 described above are provided with the same reference signs, and descriptions thereof are omitted.

The semiconductor device A50 is different from the semiconductor device A40 in the configurations of the first leads 30.

As shown in FIG. 26, in the semiconductor device A50, the exposed portions 32 of the second input terminal 30B, the two detection terminals 30E and the two dummy terminals 30F of the first leads 30 do not have a mounting surface 323. The configuration of these first leads 30 is the same as that of the first leads 30 in the semiconductor device A10. Accordingly, as shown in FIG. 27, at least a portion of the mount 322 of the exposed portion 32 of each of these first leads 30 protrudes from the bottom surface 52 of the sealing resin 50 in the thickness direction z.

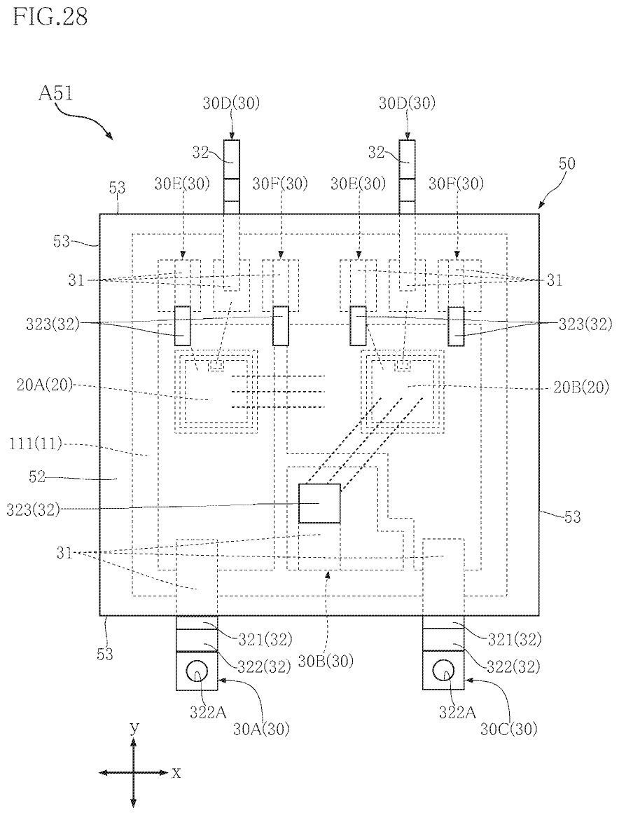

Next, a semiconductor device A51, which is a variation of the semiconductor device A50, will be described with reference to FIG. 28.

As shown in FIG. 28, the semiconductor device A51 is different from the semiconductor device A50 in the configuration of the first leads 30. In the semiconductor device A51, the exposed portion 32 of each of the first input terminal 30A, the output terminal 30C, and the two gate terminals 30D of the first leads 30 does not have a mounting surface 323. The configuration of these first leads 30 is the same as that of the first leads 30 in the semiconductor device A10.

Next, advantages of the semiconductor device A50 will be described.

The semiconductor device A50 includes the first leads 30 electrically connected to the semiconductor elements 20, and the sealing resin 50 covering a portion of each of the first leads 30. The sealing resin 50 has the bottom surface 52 facing in the thickness direction z. At least one of the first leads 30 has a mounting surface 323 exposed from and surrounded by the bottom surface 52. As such, the semiconductor device A50 can also be more compact while suppressing a decrease in the dielectric strength. Furthermore, the semiconductor device A50 has configurations similar to the semiconductor device A10, whereby the semiconductor device A50 also has advantages owing to the configurations.

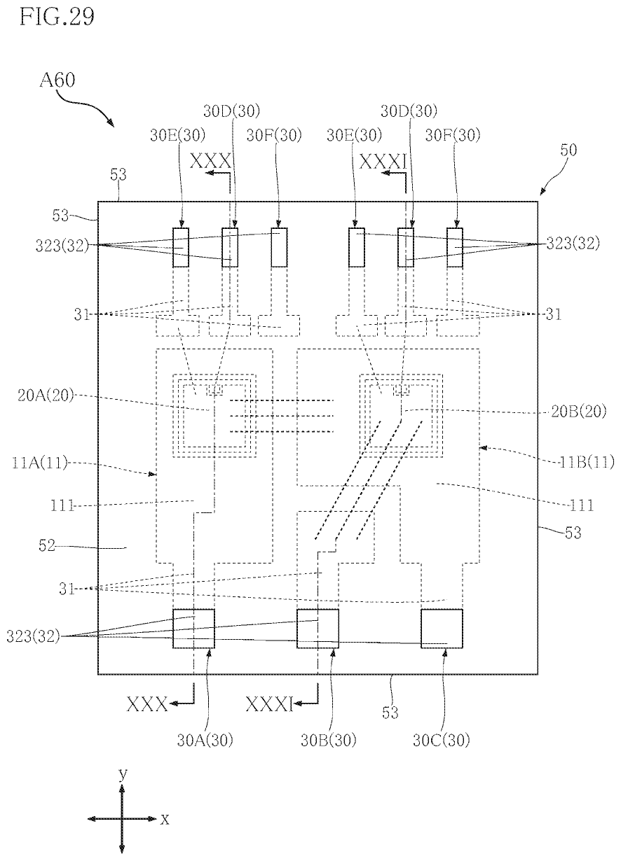

The following describes a semiconductor device A60 according to a sixth embodiment of the present disclosure, with reference to FIGS. 29 to 31. In these figures, elements that are the same as or similar to the elements of the semiconductor device A10 described above are provided with the same reference signs, and descriptions thereof are omitted.

The semiconductor device A60 is different from the semiconductor device A40 in the configurations of the support member 11, the two semiconductor elements 20, the first leads 30, the two conductive members 40, the two gate wires 41, and the two detection wires 42. The configurations of these components are the same as those of the corresponding components in the semiconductor device A30. Thus, in the following the description of the semiconductor device A60, only the configurations of the support member 11, the two semiconductor elements 20 related to the support member 11, and the first leads 30 will be described.

As shown in FIG. 29, in the semiconductor device A60, the support member 11 includes a first die pad 11A and a second die pad 11B that are spaced apart from each other. The first die pad 11A and the second die pad 11B are metal conductive plates. The first die pad 11A and the second die pad 11B are formed from the same lead frame from which the first leads 30 are formed. Accordingly, the first die pad 11A and the second die pad 11B include the same composition as the first leads 30. Each of the first die pad 11A and the second die pad 11B is thicker than each of the first leads 30. The second surface 112 of each of the first die pad 11A and the second die pad 11B is exposed from the top surface 51 of the sealing resin 50.

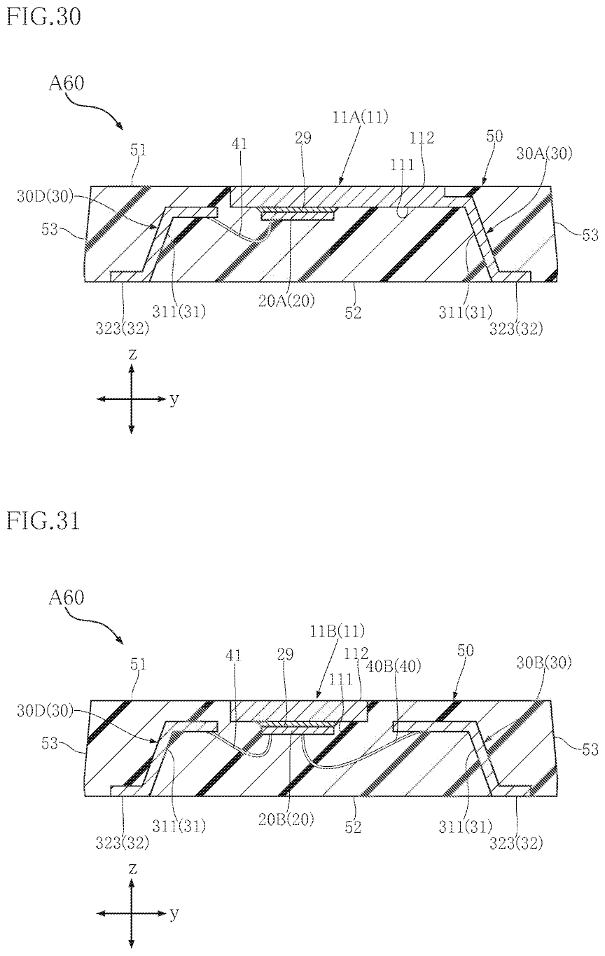

As shown in FIGS. 29 and 30, the first element 20A of the two semiconductor elements 20 is mounted on the first surface 111 of the first die pad 11A. The first electrode 21 of the first element 20A is bonded to the first surface 111 of the first die pad 11A via the bonding layer 29. Furthermore, the first input terminal 30A of the first leads 30 is connected to the first die pad 11A.

As shown in FIGS. 29 and 31, the second element 20B of the two semiconductor elements 20 is mounted on the first surface 111 of the second die pad 11B. The first electrode 21 of the second element 20B is bonded to the first surface 111 of the second die pad 11B via the bonding layer 29. Furthermore, the output terminal 30C of the first leads 30 is connected to the second die pad 11B. The first leads 30, except for the first input terminal 30A and the output terminal 30C, are located away from the support member 11 as viewed in the thickness direction z.

Next, advantages of the semiconductor device A60 will be described.

The semiconductor device A60 includes the first leads 30 electrically connected to the semiconductor elements 20, and the sealing resin 50 covering a portion of each of the first leads 30. The sealing resin 50 has the bottom surface 52 facing in the thickness direction z. At least one of the first leads 30 has a mounting surface 323 exposed from and surrounded by the bottom surface 52. As such, the semiconductor device A60 can also be more compact while suppressing a decrease in the dielectric strength. Furthermore, the semiconductor device A60 has configurations similar to the semiconductor device A10, whereby the semiconductor device A60 also has advantages owing to the configurations.

In the semiconductor device A60, all of the exposed portions 32 of the first leads 30 have the mounting surfaces 323. This makes it possible to effectively suppress a decrease in the dielectric strength of the semiconductor device A60.

This eliminates the need of the wiring layers 12 in the semiconductor device A60, as in the case of the semiconductor device A30. Furthermore, the semiconductor device A60 can achieve the same heat dissipation effect as the semiconductor device A30 and, as with the semiconductor device A30, the semiconductor device A60 can prevent the support member 11 from falling off the top surface 51 of the sealing resin 50.

The present disclosure is not limited to the embodiments described above. Various design changes can be made to the specific configurations of the elements in the present disclosure.

The present disclosure includes the configurations described in the following clauses.

Clause 1A.

A semiconductor device comprising:
a semiconductor element;
a plurality of first leads electrically connected to the semiconductor element;
a sealing resin having a top surface and a bottom surface facing away from each other in a thickness direction of the semiconductor element, the sealing resin covering the semiconductor element and a portion of each of the first leads,
wherein the sealing resin has an opening extending from the top surface to the bottom surface,
each of the plurality of first leads has a covered portion covered with the sealing resin, and an exposed portion connected to the covered portion and exposed from the sealing resin, and
as viewed in the thickness direction, at least one of the exposed portions of the plurality of first leads is housed in the opening.

Clause 2A.

The semiconductor device according to clause 1A, wherein the opening has a closed shape as viewed in the thickness direction.

Clause 3A.

The semiconductor device according to clause 2A, further comprising a plurality of second leads located opposite from the covered portions of the plurality of first leads with respect to the exposed portions of the plurality of first leads, as viewed in the thickness direction,
wherein the plurality of second leads are sandwiched by the sealing resin in the thickness direction, and
each of the plurality of second leads has an end surface facing in a direction perpendicular to the thickness direction and exposed from the sealing resin.

Clause 4A.

The semiconductor device according to clause 3A, wherein the plurality of second leads are spaced apart from the plurality of first leads.

Clause 5A.

The semiconductor device according to clause 3A, wherein the plurality of second leads are individually connected to the exposed portions of the plurality of first leads.

Clause 6A.

The semiconductor device according to clause 1A, wherein the sealing resin has a side surface connected to the top surface and the bottom surface, and
the opening is recessed from the side surface.

Clause 7A.

The semiconductor device according to any of clauses 1A to 6A, wherein as viewed in the thickness direction, all of the exposed portions of the plurality of first leads are housed in the opening.

Clause 8A.

The semiconductor device according to any of clauses 1A to 7A, wherein a cross-sectional area of the opening with respect to the thickness direction decreases from the top surface to the exposed portion of one of the plurality of first leads.

Clause 9A.

The semiconductor device according to any of clauses 1A to 8A, wherein each of the exposed portions has a base connected to the corresponding covered portion, and a mount bent from the base in a sense of the thickness direction in which the bottom surface faces, and
at least a portion of the mount protrudes from the bottom surface in the thickness direction.

Clause 10A.

The semiconductor device according to any of clauses 1A to 9A, wherein at least one of the exposed portions of the plurality of first leads has a hole penetrating through in the thickness direction.

Clause 11A.

The semiconductor device according to any of clauses 1A to further comprising a support member having a first surface and a second surface, the first surface facing in a sense of the thickness direction in which the bottom surface faces, the second surface facing away from the first surface in the thickness direction,
wherein the semiconductor element is mounted on the first surface.

Clause 12A.

The semiconductor device according to clause 11A, wherein the second surface is exposed from the top surface.

Clause 13A.

The semiconductor device according to clause 11A or 12A, further comprising a wiring layer provided on the first surface and electrically connected to the semiconductor element,
wherein the support member is an insulating plate, and
the semiconductor element is bonded to the wiring layer.

Clause 14A.

The semiconductor device according to clause 13A, wherein at least one of the covered portions of the plurality of first leads is bonded to the wiring layer.

Clause 15A.

The semiconductor device according to clause 14A, further comprising a conductive member bonded to the semiconductor element and the wiring layer.

Clause 16A.

The semiconductor device according to clause 11A or 12A, wherein the support member is a conductive plate,
at least one of the plurality of first leads is connected to the support member, and
the semiconductor element is bonded to the first surface.

Clause 17A.

The semiconductor device according to clause 16A, further comprising a conductive member bonded to the semiconductor element and at least one of the plurality of first leads.

Clause 1B.

A semiconductor device comprising:
a semiconductor element;
a plurality of first leads electrically connected to the semiconductor element; and
a sealing resin having a bottom surface facing in a thickness direction of the semiconductor element, the sealing resin covering the semiconductor element and a portion of each of the first leads,
wherein at least one of the plurality of first leads has a mounting surface exposed from the bottom surface, and
the mounting surface is surrounded by the bottom surface.

Clause 2B.

The semiconductor device according to clause 1B, wherein the mounting surface is flush with the bottom surface.

Clause 3B.

The semiconductor device according to clause 1B or 2B, wherein at least one of the plurality of first leads has an inclined surface connected to the mounting surface and inclined relative to the bottom surface, and
the inclined surface is in contact with the sealing resin.

Clause 4B.

The semiconductor device according to clause 3B, wherein as viewed in the thickness direction, the mounting surface is located farther away from a peripheral edge of the bottom surface than is the inclined surface 311.

Clause 5B.

The semiconductor device according to any of clauses 1B to 4B, further comprising a support member having a first surface and a second surface, the first surface facing in a sense of the thickness direction in which the bottom surface faces, the second surface facing away from the first surface in the thickness direction,
wherein the semiconductor element is mounted on the first surface.

Clause 6B.

The semiconductor device according to clause 5B, wherein the second surface is exposed from the sealing resin.

Clause 7B.

The semiconductor device according to clause 5B or 6B, further comprising a wiring layer provided on the first surface and electrically connected to the semiconductor element,
wherein the support member is an insulating plate, and
the semiconductor element is bonded to the wiring layer.

Clause 8B.

The semiconductor device according to clause 7B, wherein at least one of the covered portions of the plurality of first leads is bonded to the wiring layer.

Clause 9B.

The semiconductor device according to clause 8B, further comprising a conductive member bonded to the semiconductor element and the wiring layer.

Clause 10B.

The semiconductor device according to any of clauses 7B to 9B, wherein all of the plurality of first leads have the mounting surfaces.

Clause 11B.

The semiconductor device according to any of clauses 7B to 9B, wherein the sealing resin has a side surface facing in a direction perpendicular to the thickness direction and connected to the bottom surface, and
at least one of the plurality of first leads has an exposed portion exposed from the side surface.

Clause 12B.

The semiconductor device according to clause 11B, wherein at least one of the exposed portions of the plurality of first leads has a hole penetrating through in the thickness direction.

Clause 13B.

The semiconductor device according to clause 5B or 6B, wherein all of the plurality of first leads have the mounting surfaces,
the support member is a conductive plate,
at least one of the plurality of first leads is connected to the support member, and
the semiconductor element is bonded to the first surface.

Clause 14B.

The semiconductor device according to clause 13B, further comprising a conductive member bonded to the semiconductor element and at least one of the plurality of first leads.

### REFERENCE SIGNS

A10, A20, A30, A40, A50, A60: Semiconductor device
11: Support member 11A: First die pad
11B: Second die pad 111: First surface
112: Second surface 12: Wiring layer
121: First mounting layer 122: Second mounting layer
123: Relay layer 124: Pad layer
20: Semiconductor element 20A: First element
20B: Second element 21: First electrode
22: Second electrode 23: Gate electrode
29: Bonding layer 30: First lead
30A: First input terminal 30B: Second input terminal
30C: Output terminal 30d: Gate terminal
30E: Detection terminal 30F: Dummy terminal
31: Covered portion 311: Inclined surface
32: Exposed portion 321: Base
322: Mount 322A: Hole
322B: Protrusion 322C: Recess
323: Mounting surface 39: Second lead
391: End surface 40: Conductive member
40A: First member 40B: Second member
41: Gate wire 42: Detection wire
50: Sealing resin 51: Top surface
52: Bottom surface 53: Side surface
54: Opening 541: Inner peripheral surface
z: Thickness direction x: First direction
y: Second direction

1. A semiconductor device comprising:
a semiconductor element;
a plurality of first leads electrically connected to the semiconductor element;
a sealing resin having a top surface and a bottom surface facing away from each other in a thickness direction of the semiconductor element, the sealing resin covering the semiconductor element and a portion of each of the first leads,
wherein the sealing resin has an opening extending from the top surface to the bottom surface,
each of the plurality of first leads has a covered portion covered with the sealing resin, and an exposed portion connected to the covered portion and exposed from the sealing resin, and
as viewed in the thickness direction, at least one of the exposed portions of the plurality of first leads is housed in the opening.

2. The semiconductor device according to claim 1, wherein the opening has a closed shape as viewed in the thickness direction.

3. The semiconductor device according to claim 2, further comprising a plurality of second leads located opposite from the covered portions of the plurality of first leads with respect to the exposed portions of the plurality of first leads, as viewed in the thickness direction,
wherein the plurality of second leads are sandwiched by the sealing resin in the thickness direction, and
each of the plurality of second leads has an end surface facing in a direction perpendicular to the thickness direction and exposed from the sealing resin.

4. The semiconductor device according to claim 3, wherein the plurality of second leads are spaced apart from the plurality of first leads.

5. The semiconductor device according to claim 3, wherein the plurality of second leads are individually connected to the exposed portions of the plurality of first leads.

6. The semiconductor device according to claim 1, wherein the sealing resin has a side surface connected to the top surface and the bottom surface, and
the opening is recessed from the side surface.

7. The semiconductor device according to claim 1, wherein as viewed in the thickness direction, all of the exposed portions of the plurality of first leads are housed in the opening.

8. The semiconductor device according to claim 1, wherein a cross-sectional area of the opening with respect to the thickness direction decreases from the top surface to at least one of the exposed portions of the plurality of first leads.

9. The semiconductor device according to claim 1, wherein each of the exposed portions has a base connected to the corresponding covered portion, and a mount bent from the base in a sense of the thickness direction in which the bottom surface faces, and
at least a portion of the mount protrudes from the bottom surface in the thickness direction.

10. The semiconductor device according to claim 1, wherein at least one of the exposed portions of the plurality of first leads has a hole penetrating through in the thickness direction.

11. The semiconductor device according to claim 1, further comprising a support member having a first surface and a second surface, the first surface facing in a sense of the thickness direction in which the bottom surface faces, the second surface facing away from the first surface in the thickness direction,
wherein the semiconductor element is mounted on the first surface.

12. The semiconductor device according to claim 11, wherein the second surface is exposed from the top surface.

13. The semiconductor device according to claim 11, further comprising a wiring layer provided on the first surface and electrically connected to the semiconductor element,
wherein the support member is an insulating plate, and
the semiconductor element is bonded to the wiring layer.

14. The semiconductor device according to claim 13, wherein at least one of the covered portions of the plurality of first leads is bonded to the wiring layer.

15. The semiconductor device according to claim 14, further comprising a conductive member bonded to the semiconductor element and the wiring layer.

16. The semiconductor device according to claim 11, wherein the support member is a conductive plate,
at least one of the plurality of first leads is connected to the support member, and
the semiconductor element is bonded to the first surface.

17. The semiconductor device according to claim 16, further comprising a conductive member bonded to the semiconductor element and at least one of the plurality of first leads.
